(19) United States
(12) Patent Application Publication
(10) Pub. No.: US 2015/0014798 A1
(43) Pub. Date: Jan. 15, 2015

(54) ASSEMBLY FOR A MEMS ENVIRONMENTAL SENSOR DEVICE HAVING IMPROVED RESISTANCE, AND CORRESPONDING MANUFACTURING PROCESS

(71) Applicants: STMicroelectronics S.r.l., Agrate Brianza (IT); STMicroelectronics International N.V., Schiphol (NL)

(72) Inventors: Dino Faralli, Milano (IT); Benedetto Vigna, Potenza (IT); Laura Maria Castoldi, Abbiategrasso (IT)

(21) Appl. No.: 14/327,272

(22) Filed: Jul. 9, 2014

(30) Foreign Application Priority Data
Jul. 15, 2013 (IT) TO2013A000595

(51) Int. Cl. B81B 3/00; G01L 1/00; G01H 17/00; G01K 1/00; B81C 1/00; G01F 1/00

(52) U.S. Cl. CPC B81B 3/00; B81C 1/00; G01F 1/00; G01H 17/00; G01K 1/00; G01L 1/00; B81B 2201/0257; B81B 2201/0264; B81B 2201/0278
USPC 257/416; 257/415; 257/467; 257/414; 438/48

(57) ABSTRACT

Described herein is an assembly for a MEMS sensor device, which envisages: a first body made of semiconductor material, integrating a micromechanical detection structure at a first main face thereof; a cap element, set stacked on the first main face of the first body, above the micromechanical detection structure; and an adhesion structure set between the first body and the cap element, defining a gap in a position corresponding to the micromechanical detection structure. At least one first opening is defined through the adhesion structure in fluidic communication with the gap.

### BACKGROUND

1. Technical Field

The present disclosure relates to an assembly for a MEMS (Micro-Electro-Mechanical Systems) environmental sensor device having improved resistance, and to a corresponding manufacturing process.

2. Description of the Related Art

The increasing use is known, for example in portable electronic apparatuses such as laptops, tablets, smartphones, digital audio players, photographic or video cameras, and consoles for videogames, of sensor devices including micromechanical detection structures, which are made, at least in part, of semiconductor materials and employ MEMS technology.

The aforesaid sensor devices have advantageous features, amongst which extremely compact dimensions, reduced consumption levels and good electrical performance, and are used, for example, for inertial navigation applications, for implementing user interfaces for detecting displacements in a three-dimensional space, or, in the case of an environmental sensor device, for detecting environmental quantities (such as pressure, humidity, flow rate, temperature).

The assembly of the sensor devices in general involves a package, which houses the corresponding micromechanical detection structure, and possible control circuits associated thereto, typically provided as ASICs (Application-Specific Integrated Circuits), and constitutes the mechanical and electrical interface with respect to the external environment.

In particular, in an environmental MEMS sensor device, the assembly is configured in such a way that the micromechanical detection structure comes into contact with the external environment to enable detection of the environmental quantities of interest.

For this purpose, the assembly generally envisages the presence of one or more access holes, typically provided through the corresponding package, which are designed to set the external environment in fluidic communication with the micromechanical detection structure of the sensor device and thus enable detection operations.

A disadvantage of such an assembly is linked to the possibility of particles, dust, or other material, arriving from the external environment, coming into contact with the micromechanical detection structure of the sensor device, thus jeopardizing proper operation thereof. For instance, such particles may deposit on a membrane or some other moving element of the micromechanical detection structure, thus altering the possibility of movement and hence the sensitivity of detection.

Furthermore, micromechanical detection structures may also be damaged by humidity or electromagnetic radiation present in the external environment.

In other words, the presence of the access holes exposes the micromechanical detection structures to contamination from the external environment, with possible risks of damage or failure.

### BRIEF SUMMARY

According to one or more embodiments of the present disclosure, an assembly for an environmental MEMS sensor device and a corresponding manufacturing process are provided. In one embodiment, an assembly for a MEMS sensor device includes a first semiconductor body that has a first main surface. The first semiconductor body integrates a micromechanical detection structure at the first main face. The assembly further includes a cap element coupled to the first main face of said first body above said micromechanical detection structure. An adhesion structure is located between said first body and said cap element and defines a gap in front of said micromechanical detection structure. The adhesion structure has at least one first through hole that places the gap in fluidic communication with an environment outside of the cap element.

### BRIEF DESCRIPTION OF THE SEVERAL VIEWS OF THE DRAWINGS

For a better understanding of the present disclosure, preferred embodiments thereof are now described purely by way of non-limiting example and with reference to the attached drawings, wherein:

FIG. 1 is a schematic representation in plan view of a portion of an environmental MEMS sensor device according to one embodiment of the present solution;

FIGS. 2 and 3 are schematic cross-sectional views of the environmental MEMS sensor device of FIG. 1, taken along respective lines of section II-II and III-III appearing in FIG. 1;

FIG. 4 shows a schematic representation in plan view of an environmental MEMS sensor device according to a further embodiment of the present solution;

FIGS. 5A-5C are schematic plan views of a portion of the environmental MEMS sensor device in different steps of a corresponding assembly process; and

FIG. 6 is a schematic representation in cross-sectional view of an environmental MEMS sensor device, according to yet a further embodiment of the present solution.

### DETAILED DESCRIPTION

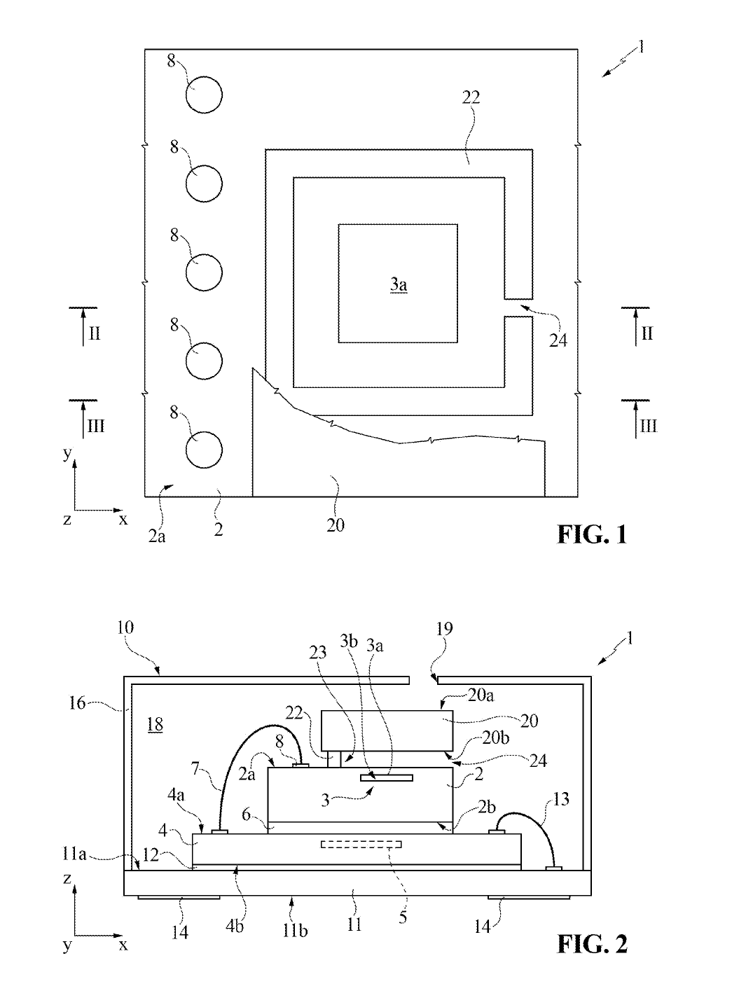

With reference to FIGS. 1-3, an embodiment of an assembly for an environmental MEMS sensor device, designated as a whole by 1, is now described. The MEMS sensor device 1 is, for example, a pressure-sensor device, a temperature sensor, a humidity sensor, a flow-rate sensor, a microphone.

The MEMS sensor device 1 comprises a first die 2, including semiconductor material, provided in which is a micromechanical detection structure 3, which comprises appropriate detection elements, for example a mobile mass, a membrane, or other deformable element. In the example illustrated, the micromechanical detection structure 3 comprises a membrane 3a, suspended over a cavity 3b, formed in a surface portion of the first die 2.

In particular, the first die 2 has a first main surface, or front surface, 2a, lying in a horizontal plane xy, at which the membrane 3a of the micromechanical detection structure 3 is provided, and a second main surface, or back surface, 2b, opposite to the front surface 2a along a vertical axis z, transverse to the horizontal plane xy.

The MEMS sensor device 1 further comprises a second die 4, including semiconductor material, provided in which is an electronic circuit 5, designed to be operatively coupled to the micromechanical detection structure 3, comprising (in a way not illustrated in detail) appropriate circuit components, for carrying out acquisition and processing operations (for example, in terms of amplification and filtering) of one or more electrical quantities detected by the micromechanical detection structure 3.

In particular, the second die 4 has a respective front surface 4a, lying in the horizontal plane xy, at which the electronic circuit 5 is provided, and a respective back surface 4b, opposite to the front surface 4a along the vertical axis z.

The first die 2 is set on the second die 4 along the vertical axis z, or, in other words, the two dice 2, 4 are stacked along one the same vertical axis z. An adhesive layer 6 is set between a portion of the back surface 2b of the first die 2 and a corresponding portion of the front surface 4a of the second die 4 in order to provide the mechanical coupling between the dice 2, 4.

Electrical coupling between the micromechanical detection structure 3 in the first die 2 and the electronic circuit 5 in the second die 4 is obtained by means of the wire-bonding technique, i.e., using electrical wires 7, which electrically connect corresponding contact pads, designated as a whole by 8, carried by the respective front surfaces of the two dice 2, 4.

The MEMS sensor device 1 further comprises a package 10, which houses the dice 2, 4, ensuring protection from the external environment and moreover providing the electrical connections between the same external environment and the electronic circuit 5 and/or the micromechanical detection structure 3.

In the embodiment illustrated, the package 10 comprises a base support 11, having an internal surface 11a, facing the inside of the package 10, and an external surface 11b, facing the external environment.

The second die 4 integrating the electronic circuit 5 is coupled to the internal surface 11a of the base support 11 by means of a respective adhesive layer 12, which is set between the same internal surface 11a and the back surface 4b of the second die 4. Electrical wires 13 electrically connect pads carried by the front surface 4a of the second die 4 to corresponding pads, or electrical paths, carried by the internal surface 11a of the base support 11. Furthermore, the base support 11 carries, on its external surface 11b, appropriate electrical-connection elements 14 for connection to the external environment, for example to a printed-circuit board (PCB), in the form, for instance, of conductive lands or bumps.

Electrical connection vias (not illustrated) are provided through the base support 11 to set in connection the pads or electrical paths carried by the internal surface 11a of the base support 11 and the electrical-connection elements 14.

The package 10 further comprises a covering 16, in the example constituted by a hollow cup-shaped body, defining an internal space 18 of the package 10. The covering 16 may be made of semiconductor material, silicon, or else pre-molded plastic, with a possible internal metal coating in order to reduce electromagnetic disturbance.

The covering 16 is coupled onto the internal surface 11a of the base support 11 and houses the assembly of the dice 2, 4 in the internal space 18. In greater detail, the covering 16 has side-wall portions, having an extension along the vertical axis z, and a top portion, facing the internal surface 11a of the base support 11 and arranged on the side-wall portions.

In particular, one or more access holes 19 are provided through the top portion of the covering 16 in order to set the external environment in fluidic communication with the internal space 18.

As highlighted previously, the above fluidic communication between the external environment and the internal space 18 in the package 10, or, in general, the micromechanical detection structure 3 integrated in the first die 2, is utilized to enable detection of the quantity or quantities of interest by the micromechanical detection structure 3.

In the embodiment illustrated, the access hole 19 through the covering 16 of the package 10 is set vertically in a position corresponding to the micromechanical detection structure 3.

The assembly for the MEMS sensor device 1 moreover envisages a cap element 20, set above the front surface 2a of the first die 2, in particular on the portion of the first die 2 in which the micromechanical detection structure 3 is integrated (in the example, above the membrane 3a). The cap element 20 leaves exposed the portion of the front surface 2a, where the contact pads 8 are provided.

The cap element 20 is made by a solid body, without openings, or holes, which has a substantially parallelepipedal shape and is made of semiconductor material, for example silicon, or else of some other material, for example plastic material, polymeric material (such as a dry polymeric film, or dry resist), ceramic material, or glass. The cap element 20 has a respective front face 20a and a respective back face 20b, which are substantially parallel to one another and planar.

In the embodiment, the cap element 20 is set along the vertical axis z between the micromechanical structure 3 integrated in the first die 2 and the access hole 19 provided through the covering 16 of the package 10.

The cap element 20 is coupled to the first die 2 by means of an adhesion structure 22, which is set between the front surface 2a of the first die 2 and the back face 20b of the cap element 20.

The adhesion structure 22 includes adhesive material, for example a polymeric film, a metal material (for example, gold, copper, or tin), or a welding paste (for example, glass frit). In the embodiment illustrated, the adhesion structure 22 is ring-shaped (for example, having the shape of a rectangular or square ring) in plan view, i.e., parallel to the horizontal plane xy.

In particular, in this embodiment, the adhesion structure 22 surrounds the surface portion of the first die 2 where the micromechanical detection structure 3 is provided (in the example shown, it surrounds the portion where the membrane 3a is made).

The adhesion structure 22 has a certain thickness along the vertical axis z, so that between the main faces of the first die 2 and of the cap element 20 a gap 23 is present.

According to a particular aspect of the present solution, the adhesion structure 22 is not continuous throughout its perimeter. Through the adhesion structure 22, at least one first side opening 24 is indeed defined, which traverses the entire width of the adhesion structure 22 laterally at a first section thereof, hence setting the gap 23 in communication with the internal space 18 of the package 10. The dimensions of the side opening 24 may vary according to the constructional specifications. In any case, they are extremely small, in the region of a few microns, along the vertical axis z.

Due to the presence of the side opening 24 an uninterrupted fluidic path between the external environment, the internal space 18 in the package 10, the gap 23, and, hence, the micromechanical detection structure 3 integrated in the first die 2 is thus created. In this way, the micromechanical detection structure 3 is able to detect the environmental quantity or quantities of interest (pressure, humidity, temperature, or generally any other quantity). In particular, this fluidic path comprises a substantially horizontal stretch, i.e., one that extends parallel to the horizontal plane xy, defined by the aforesaid side opening 24.

Advantageously, the cap element 20 protects the underlying micromechanical detection structure 3 from any possible contamination or contaminating agents coming from the external environment (since it is in fact set between the access hole 19 and the gap 23 overlying the micromechanical detection structure 3). The side opening 24 enables access of air (and/or other gases) coming from the external environment, but the assembly structure is such that particles or other contaminating agents do not penetrate into the aforesaid gap 23 through the side opening 24. The dimensions of the side opening 24 are such as to prevent contaminating particles from depositing on the micromechanical structure 3, by penetrating into the gap 23, enabling, instead, free passage of air (and/or other gases) from the external environment.

In particular, it is emphasized that in this embodiment, the fluidic path towards the micromechanical structure 3 is defined exclusively through the side opening or openings 24, given that openings are not provided through the cap element 20.

As shown in FIG. 4, a plurality of further side openings 24, arranged, for example, at regular intervals along one or more portions of the adhesion structure 22 may be provided through the same adhesion structure 22. The side openings 24 traverse the entire width of the adhesion structure 22 at respective sections, to provide a corresponding number of passages towards the gap 23.

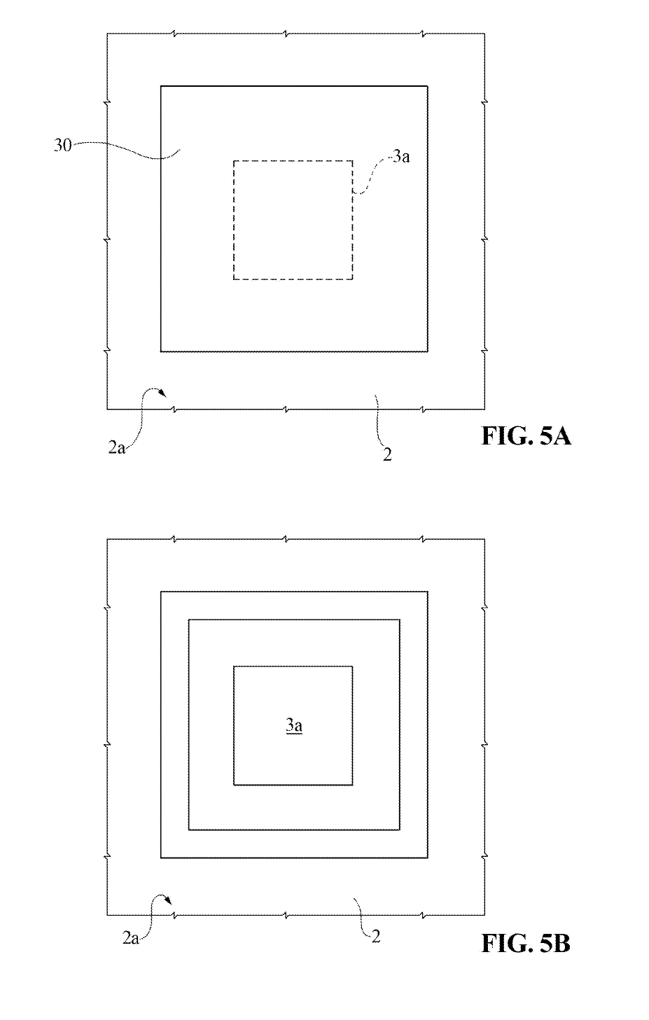

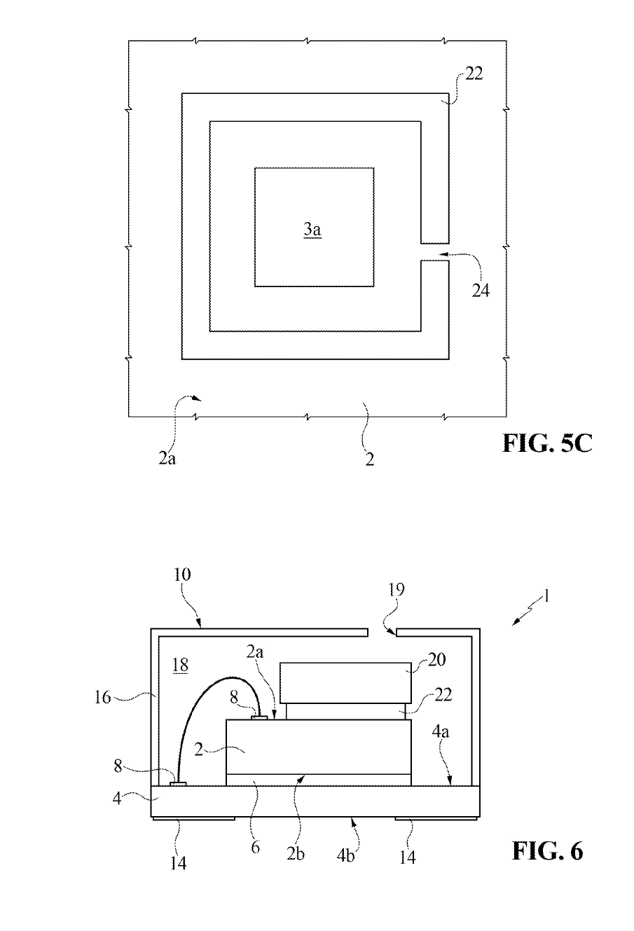

The process for manufacturing the described assembly, as regards the relevant steps regarding formation of the aforesaid fluidic path towards the micromechanical detection structure 3, thus envisages (FIG. 5A) that an adhesion layer 30 consisting of purposely provided adhesive material is formed on the first main surface 2a of the first die 2. The adhesion layer 30 has an extension in plan view (in the horizontal plane xy) sufficient to cover the extension of the underlying portion of the first die 2, integrated in which is the micromechanical detection structure 3, and has a desired thickness (as a function of the desired height along the vertical axis z of the gap 23 that will subsequently be formed). In the example, the adhesion layer 30 has an extension in the horizontal plane xy greater than the corresponding extension of the underlying membrane 3a.

As shown in FIG. 5B, the adhesion layer 30 is appropriately patterned, for example via chemical etching using the photolithographic technique, for removal of a central portion thereof, which leaves exposed the underlying micromechanical detection structure 3 (in the example, the corresponding membrane 3a).

In this same processing step, or, alternatively, in a step immediately subsequent thereto (FIG. 5C), the adhesion layer 30 (or its remaining portion) is appropriately patterned, via discontinuous patterning, to define the side opening or openings 24. In this way, the adhesion structure 22 is defined on the first main surface 2a of the first die 2.

Alternatively, the adhesion layer 22 may be directly deposited using selective deposition techniques, such as, for example, printing or screen-printing techniques.

In a way not illustrated, a bonding operation is carried out (in particular the so-called “wafer-to-wafer” or “chip-to-wafer” bonding) between the first die 2 and the cap element 20 (which meanwhile has been provided), exploiting for this purpose the adhesion structure 22. In this way, the gap 23 on the micromechanical detection structure 3, and the passages of the fluidic path towards the gap 23 through the side opening or openings 24 are defined.

The advantages of the solution described are clear from the foregoing discussion.

In particular, the presence of the cap element 20 on the first die 2 enables protection of the micromechanical detection structure 3 integrated in the first die 2 from potentially harmful interactions with the external environment (for example, on account of contamination by particles, dust, moisture). The MEMS sensor device 1 thus has an improved resistance in regard to environmental contamination.

Moreover, the at least one side opening 24 enables definition of a fluidic path from the external environment towards the micromechanical detection structure 3, thus enabling detection of the environmental quantity or quantities of interest.

The solution described is extremely simple and inexpensive to manufacture, and with minor modifications is suited to known assembly structures and to the corresponding manufacturing processes.

Finally, it is clear that modifications and variations may be made to what has been described and illustrated herein, without thereby departing from the scope of the present disclosure.

In particular, it is evident that the materials that may be used to form the cap element 20 and the adhesion structure 22 may differ from the ones referred to previously by way of example. In general, to guarantee the aforesaid advantage of economy of manufacture, the choice will be for low-cost materials.

Furthermore, the adhesion structure 22 may possibly be constituted by a plurality of portions that are distinct from one another, separated by the side openings 24 (which in this case may have larger dimensions in the horizontal plane xy); for example, these distinct portions may be set at the edges of the cap element 20, or else centrally with respect to the sides of the same cap element 20, being in any case positioned at a distance from the micromechanical structure 3. Also in this case, the manufacturing process may envisage selective deposition, or direct formation, of said distinct portions of the adhesion structure 22 locally in the positions of interest, or may envisage distinct steps of formation and subsequent patterning.

The general manufacturing of the assembly may even differ from what has been described previously as regards aspects that are non-substantial for the purposes of the discussed solution.

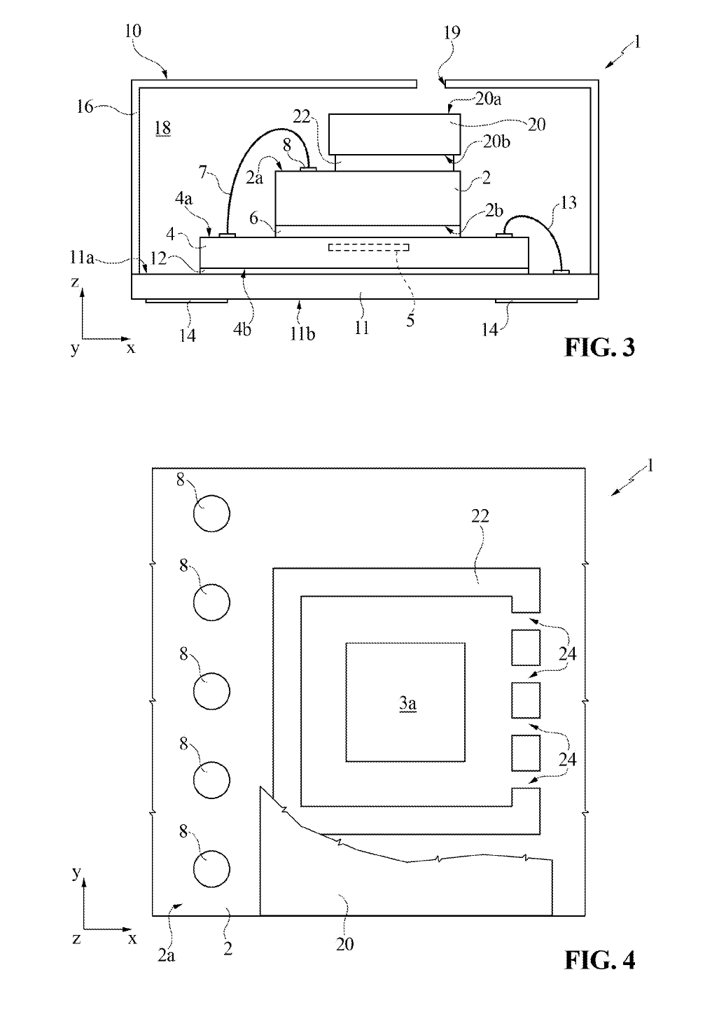

For instance, FIG. 6 shows (in cross-sectional view similar to the cross-sectional view of FIG. 3) a possible variant embodiment, where the package 10 does not have the base support 11. In this case, it is the same second die 4 that operates as a base for the package 10, and as a mechanical and electrical interface of the MEMS sensor device 1 in regard to an external printed circuit (not illustrated), at its back face 4b.

As a further variant, the assembly may even not envisage the presence of the second die 4, integrating the electronic circuit 5 associated to the micromechanical detection structure 3 (in the case where processing of the signals detected is entirely entrusted to external circuits).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An assembly for a MEMS sensor device, the assembly comprising:
a first body including semiconductor material, the first body having a first main face and integrating a micromechanical detection structure at the first main face;
a cap element coupled to the first main face of said first body and facing said micromechanical detection structure; and
an adhesion structure between said first body and said cap element defining a gap between said micromechanical detection structure and said cap element, the adhesion structure including an opening that places the gap in fluidic communication with an environment external to said gap.

2. The assembly according to claim 1, wherein said adhesion structure is provided around said micromechanical detection structure and defining a ring structure that is closed except in a region corresponding to said first opening.

3. The assembly according to claim 1, wherein said first opening defines a fluidic path that extends laterally through said adhesion structure and parallel to said first main face of said first body.

4. The assembly according to claim 1, the opening is one of a plurality of openings in the adhesion structure that place the gap in fluidic communication with the environment external to said gap.

5. The assembly according to claim 1, wherein said adhesion structure includes adhesive material.

6. The assembly according to claim 1, wherein said cap element is a solid body, without openings towards said gap.

7. The assembly according to claim 1, further comprising a package having a covering that houses said first body and said cap element and defines an internal space, at least one access hole being provided through said covering that places said internal space in fluidic communication with an environment external to said assembly, wherein said first opening places said internal space in fluidic communication with said gap.

8. The assembly according to claim 7, wherein said cap element is located between said access hole of the covering and said micromechanical detection structure integrated in said first body.

9. The assembly according to claim 7, further comprising:
a second body including semiconductor material and integrating an electronic circuit that is operatively coupled to said micromechanical detection structure; and
said first body being coupled to said second body.

10. The assembly according to claim 9, wherein said package further comprises a base support that is coupled to said second body, the base supporting providing a mechanical and electrical interface for the assembly.

11. The assembly according to claim 1, wherein said micromechanical structure includes at least one deformable element suspended over a cavity provided in said first body.

12. The assembly according to claim 1, wherein said MEMS sensor device is at least one of a pressure sensor, a temperature sensor, a humidity sensor, a flow sensor, and a microphone.

13. A process for assembling a MEMS sensor device, the method comprising:
forming an adhesion structure on at least one of a first main face of a first semiconductor body integrating a micromechanical detection structure and a cap element, wherein forming the adhesion structure includes forming a perimeter having a outward of the micromechanical detection structure, the perimeter having an opening; and
coupling the cap element and said first body together using said adhesion structure and defining a gap facing said micromechanical detection structure, wherein the opening through said adhesion structure places the gap in fluidic communication with an external environment.

14. The process according to claim 13, wherein forming the adhesion structure comprises patterning said adhesion structure prior to the coupling step.

15. The process according to claim 13, wherein:
forming an adhesion structure comprises forming an adhesion layer on the first main face of said first body; and
the process further comprising removing selective portions of said adhesion layer to form said opening outward of said micromechanical detection structure.

16. An assembly for a MEMS sensor device, the assembly comprising:
a first semiconductor body having a first main surface;
a micromechanical detection structure formed in the semiconductor body at the first main face;
a cap element having a first portion coupled to the first main face of said first body and a second portion that is spaced apart from first main face by a gap, the gap located facing said micromechanical detection structure; and
an adhesion structure between said first body and said first portion of said cap element defining the gap, the adhesion structure including an opening that placing the gap in fluid communication with an environment outside of the gap.

17. The assembly according to claim 16, wherein opening in the adhesion structure is one of a plurality of openings.

18. The assembly according to claim 17, wherein the plurality of openings are located along one side of the adhesive structure.

19. The assembly according to claim 16, wherein the adhesive structure is at least one of a polymeric film, a metal material, and a welding paste.

20. The assembly according to claim 16, wherein the adhesive structure extends around a perimeter of the cap element except at the opening.

21. The assembly according to claim 16, wherein the first portion of the cap element has a first thickness and the second portion of the cap element has a second thickness, the first thickness being the same as the second thickness.

22. The assembly according to claim 16, further comprising a package located around and spaced apart from the cap element to form an interior portion, the package having an access hole that places the interior portion in fluid communication with an environment external to the assembly.

23. The assembly according to claim 22, further comprising a fluid path that places the gap in fluid communication with the environment external to the assembly, the fluid path including the gap, the opening in the adhesion structure, the interior portion of the package, and the access hole.
